(19) United States
(12) Patent Application Publication
(10) Pub. No.: US 2008/0080245 A1
(43) Pub. Date: Apr. 3, 2008

(54) P-CHANNEL MEMORY AND OPERATING METHOD THEREOF

(76) Inventor: Chih-Cheng Liu, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/306,092

(22) Filed: Dec. 15, 2005

(30) Foreign Application Priority Data
May 19, 2005 (TW) 94116259

(51) Int. Cl. G11C 11/34; H01L 29/788

(52) U.S. Cl. 365/185.15; 257/315; 257/E29.3

(57) ABSTRACT

A P-channel memory is provided. Each memory unit is constructed of a substrate, a gate structure, a first charge trapping layer, a second charge trapping layer, a first source/drain, and a second source/drain. The gate structure is located above the substrate. The first charge trapping layer and the second charge trapping layer are located on both sidewalls of the gate structure for storing two bit of data in a single memory unit. The first source/drain and the second source/drain are located in the substrate on both sides of the gate structure.

### CROSS-REFERENCE TO RELATED APPLICATION

This application claims the priority benefit of Taiwan application serial no. 94116259, filed on May 19, 2005. All disclosure of the Taiwan application is incorporated herein by reference.

### BACKGROUND OF THE INVENTION

1. Field of Invention

The present invention is related to a memory device. In particular, it is related to an operating method of a P-channel memory.

2. Description of Related Art

An electrically erasable programmable read only memory (EEPROM) in nonvolatile memory includes advantages such as the capability of conducting repeated data storage, read, erase, and other functions, and having data not disappearing after a power outage; therefore, it is becoming the memory device widely adopted in personal computers and electronic devices.

The conventional EEPROM uses doped polysilicon to make a floating gate and a control gate. The insulation layer between a gate and a substrate and between a gate and another gate is a silicon oxide layer.

However, the aforementioned EEPROM requires the forming a plurality of polysilicon layers and a plurality of silicon oxide layers. During the fabrication process, it goes through many mask procedures, which prolongs the fabrication process and entails higher fabrication cost.

Therefore, the U.S. Pat. No. 6,678,190 proposes an erasable programmable read only memory (EPROM), which does not require the forming of a plurality of polysilicon layers, but instead is using two adjacent but separate P-type MOS transistors as select gate and floating gate. Referring to FIG. 1A, a cross-sectional view schematically illustrating the structure of a conventional EPROM. A N-type well 101 is disposed in a substrate 100. Two adjacent P-type metal oxide semiconductor (MOS) transistors 110 and 120 are disposed above the N-type well 101. The gate 115 above the P-type MOS transistor 110 is used as the select gate, and the gate 125 above the P-type MOS Transistor 110 is used as the floating gate. This type of read only memory can be integrated with the Complementary MOS (CMOS) transistor for process integration. And because of not requiring to form the control gate, it can therefore reduce device size.

However, referring to FIG. 1B, it is a top view schematically illustrating the structure of the aforementioned EPROM. It is clearly evident that a horizontal dimensions 150 for the memory unit is very wide. In fact the entire memory unit size reaches 15F², which is extremely not suitable for device integration and is violating the current trend for integrated circuit towards size miniaturization. Furthermore, the memory unit possesses longer passage length, as a result, the memory unit program and erase efficiencies are lower.

In addition, the memory device, in accordance to the type of passage, is identified as a P-channel memory and a N-channel memory. The P-channel memory has higher electron injection efficiency, higher device integration, advantages such as the ability to avoid reliability issues caused by hot hole injection, and reduced oxidation layer electric field during electron injection. In addition, its electron injection rate is faster than N-channel memory, and it has lower power loss, lower power consumption, lower programming voltage, and other advantageous characteristics; therefore, it is currently widely used in the semiconductor-related industries.

However, the conventional P-channel memory, because of using the Fowler-Nordheim Tunneling or the hot hole injection operating method, has lower electron injection efficiency. As a result, larger voltage is applied by providing larger current so as to increase the rate of the erase operation. Its power consumption is high, which has longer time requirement. And if the applied voltage is high, it is easy to lead to high current leakage, causing reduction in memory device reliability. Furthermore, as the device integration increases, the high current leakage becomes more severe, which would greatly restrict the degree of miniaturization for the size of the device.

### SUMMARY OF THE INVENTION

As can be seen from the aforementioned, the objective of the present invention is for providing a P-channel memory, which has a small size, consists of a simple process, and stores two bit of data in a single memory cell, thus helping to increase device integration.

Another objective of the present invention is for providing an operating method for a P-channel memory, having reduced operating voltage requirement, ability to conserve power consumption, and increased program/erase efficiency, thus shortening the operating speed for the device and increasing device reliability .

The present invention proposes a P-channel memory, which includes a first memory unit. A first memory unit is, for example, constructed of a substrate, a gate structure, a first charge trapping layer, a second charge trapping layer, a first source/drain, and a second source/drain. The gate structure is disposed above the substrate. In addition, the first charge trapping layer and the second charge trapping layer are disposed at both sidewalls of the gate structure for storing two bit in the first memory unit. The first source/drain and the second source/drain are disposed in the substrate at both sidewalls of the gate structure.

According to the P-channel memory described in an embodiment of the present invention, a tunnel dielectric layer is further included between the aforementioned first charge trapping layer and the sidewall of the gate structure and also between the second charge trapping layer and the sidewall of the gate structure. An insulation layer is further included at the exterior side of the first charge trapping layer and the second charge trapping layer.

According to the P-channel memory described in an embodiment of the present invention, the aforementioned material for the charge trapping layer is, for example, silicon nitride. The material for the tunnel dielectric layer is, for example, silicon oxide. The material for the insulation layer is, for example, silicon oxide.

According to the P-channel memory described in an embodiment of the present invention, a P-type ion is doped in the aforementioned first source/drain and the second source/drain.

According to the P-channel memory described in an embodiment of the present invention, a second memory unit is further included, wherein the second memory unit and a first memory unit having the same structure, and the first memory unit and the second memory unit sharing the first source/drain.

According to the P-channel memory described in an embodiment of the present invention, the aforementioned gate structure includes the gate dielectric layer and the gate stacked on the substrate sequentially. The material for the gate is, for example, P-type polysilicon.

Because the charge trapping layer is disposed at the sidewall of the gate structure for the aforementioned P-channel memory, whereas the silicon oxide/silicon nitride/silicon oxide (ONO) layer for the conventional silicon nitride read only memory is disposed below the gate, they are very much different. The structure for the present invention can greatly reduce the size of the device. In addition, the process for the present invention is simple, without requiring photolithography process having multiple masks, the required fabrication time for the device can therefore be reduced. Furthermore, because the charge trapping layer is disposed at both sidewalls of the gate structure, two-bit data can be stored in a single memory cell to increase device integration.

The present invention proposes an operating method for a P-channel memory device. The P-channel memory is, for example, a substrate, a gate disposed above the substrate, a first charge trapping layer and a second charge trapping layer disposed at both sidewalls of the gate, and a first source/drain and a second source/drain disposed in the substrate at both sidewalls of the gate. The operating method is, for example, described as follows: during the program operations, using the P-channel memory storing the first bit, electrons are injected into the second charge trapping layer; during the erase operation, first voltage is applied at the first source/drain, second voltage is applied at the second source/drain, third voltage is applied at the gate, and fourth voltage is applied at the substrate. The tertiary hot hole mechanism is used to inject the hot hole into the second charge trapping layer for erasing the preexisting first bit stored in the P-channel memory. In addition, the absolute value of the voltage difference between the third voltage and the fourth voltage is less than or equal to 6V, and the second voltage is less than the third voltage.

According to the operating method for the P-channel memory described in an embodiment of the present invention, during the aforementioned program operation, a fifth voltage is further included to be applied at the first source/drain. A sixth voltage is applied at the second source/drain. A seventh voltage is applied at the gate. And an eighth voltage is applied at the substrate. Electrons are injected into the second charge trapping layer, and the first bit is stored in the P-channel memory. In addition, the sixth voltage is less than the seventh voltage, and the seventh voltage is larger than the third voltage.

According to the P-channel memory described in an embodiment of the present invention, the aforementioned second charge trapping layer and the first bit are disposed on the same side.

According to the operating method for the P-channel memory described in an embodiment of the present invention, during the program operation, electrons injecting into the first charge trapping layer are further included along with the storing of the second bit in the P-channel memory. During the erase operation, the second voltage is applied at the first source/drain, the first voltage is applied at the second source/drain, the third voltage is applied at the gate, and the fourth voltage is applied at the substrate. Tertiary hot hole mechanism is used to inject the hot hole into the first charge trapping layer for erasing the second bit in the previously stored P-channel memory. During the program operation, the sixth voltage is further applied at the first source/drain, the fifth voltage is applied at the second source/drain, the seventh voltage is applied at the gate, and the eighth voltage is applied at the substrate. Electrons are injected into the first charge trapping layer, storing the second bit into the P-channel memory.

According to the P-channel memory described in an embodiment of the present invention, the aforementioned first charge trapping layer and second bit are disposed on the same side.

According to the P-channel memory described in an embodiment of the present invention, the first voltage of the aforementioned is 0V, the second voltage is about −3V to −4V, the third voltage is about −2.5V to −3.5 V, and the fourth voltage is about 2.8V to 3.4 V.

According to the P-channel memory described in an embodiment of the present invention, the aforementioned method in injecting the hot electron into the charge trapping layer includes the channel hot electron injection (CHEI) method.

According to the P-channel memory described in an embodiment of the present invention, the material for the aforementioned first charge trapping layer and the second charge trapping layer is, for example, silicon nitride. The material for the aforementioned gate is, for example, doped polysilicon. The exterior side of the aforementioned first charge trapping layer and second charge trapping layer further can include an insulation layer, wherein, the material of the insulation layer is, for example, silicon oxide.

The present invention proposes an operating method for the P-channel memory, because of the adoption of the tertiary hot hole mechanism for conducting erase operation, the required operating voltage is therefore lower, thus saves on power consumption, increases program/erase efficiency, and proceeds to shorten the operating speed for the device. In addition, because of the lower operating voltage, issues regarding leakage current can further be prevented and device reliability is increased.

Furthermore, as a result of the charge trapping layer disposed at the sidewall of the gate structure, the charge storage is therefore at both sidewalls of the gate structure unlike the conventional silicon nitride read only memory with a memory cell having two bit which becomes mutually affected and produces the issue of the so-called electron secondary effect, able to increase device reliability.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view schematically illustrating a structure for a conventional EPROM.

FIG. 1B is a top view schematically illustrating the structure of the conventional EPROM.

FIG. 2A is a top view schematically illustrating the structure a P-channel memory according to an embodiment of the present invention.

FIG. 2B is a cross-sectional view schematically illustrating of the line A-A′ of FIG. 2A in the structure of a P-channel memory.

FIG. 3 is a schematic diagram illustrating the program operation for the P-channel memory according to an embodiment of the present invention.

FIG. 4 is a schematic diagram illustrating the erase operation for the P-channel memory according to an embodiment of the present invention.

FIG. 5 is a schematic diagram illustrating the program operation for the P-channel memory according to an embodiment of the present invention.

FIG. 6 is a schematic diagram illustrating the erase operation for the P-channel memory according to an embodiment of the present invention.

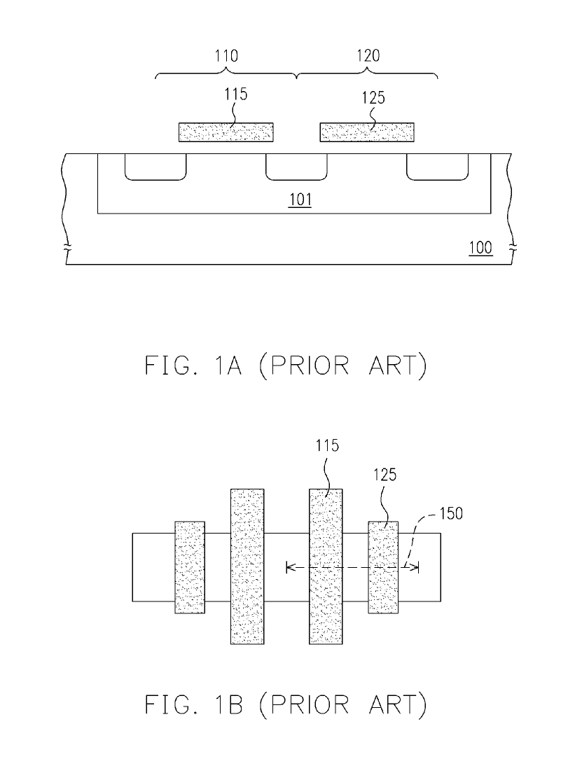

### DESCRIPTION OF THE PREFERRED EMBODIMENTS

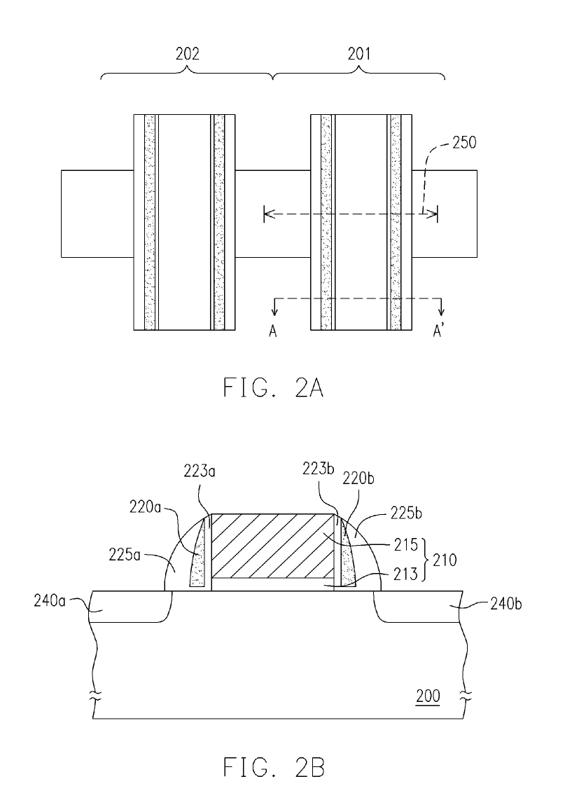

FIG. 2A is a top view schematically illustrating a structure of a P-channel memory for an embodiment of the present invention. FIG. 2B is a cross-sectional view of the structure of the P-channel memory schematically illustrated in the line A-A′ in FIG. 2A.

Referring to FIG. 2A and FIG. 2B, the P-channel memory for the present invention includes a memory unit 201. The memory unit 201, for example, is constructed of a substrate 200, a gate structure 210, a charge trapping layer 220a, a charge trapping layer 220b, a source/drain 240a, and a source/drain 240b. Wherein, the gate structure 210 is disposed above the substrate 200. The charge trapping layer 220a and the charge trapping layer 220b are disposed at both sidewalls of the gate structure 210 for storing the two bit in the memory unit 201. The source/drain 240a and the source/drain 240b are disposed in the substrate 200 at both sidewalls of the gate structure 210.

Wherein, the substrate 200 is, for example, a silicon substrate. The gate structure 210 above the substrate 200 includes, for example, a gate dielectric layer 213 and a gate 215. The material for the gate dielectric layer 213 is, for example, silicon oxide. The material for the gate 215 is, for example, P-type polysilicon. The material for the charge trapping layer 220a and the charge trapping layer 220b, for example, is silicon nitride. Wherein, a tunnel dielectric layer 223a is included between the sidewall of the charge trapping layer 220a and the gate structure 210 and between the charge trapping layer 220a and the substrate 200. Similarly, a tunnel dielectric layer 223b is also included between the sidewall of the charge trapping layer 220b and the gate structure 210 and between the charge trapping layer 220b and the substrate 200. Furthermore, the insulation layer 225a and the insulation layer 225b are disposed at the exterior side of the charge trapping layer 220a and the charge trapping layer 220b. The material for the tunnel dielectric layers 223a, 223b can be silicon oxide. The material for the insulation layers 225a, 225b, for example, is silicon oxide. The tunnel dielectric layers 223a, 223b and the insulation layers 225a, 225b can also be other similar materials. The material for the charge trapping layers 220a, 220b is not limited to silicon nitride, and can be material capable of charge injection, for example, tantalum oxide layer, strontium titanate layer, and hafnium oxidized layer. The source/drain 240a and the source/drain 240b, for example, is a P-type ion doped therein.

Furthermore, the P-channel memory further includes a memory unit 202. The memory unit 202 and the memory unit 201 have the same structure, and the memory unit 201 and the memory unit 202 share the source/drain 240a. This type of structure can increase device integration. In addition, the horizontal dimension for the memory unit 201 is relatively small. The size for the memory unit is 9F², which is much lower from the conventional device size for EPROM. This further corresponds to the development requirements for integrated circuit.

The aforementioned P-channel memory, because the charge trapping layer is disposed at the sidewall of the gate structure and the silicon oxide/silicon nitride/silicon oxide (ONO) layer of the conventional silicon nitride read only memory is disposed below the gate, they are very much different. This structure can greatly shrink the device size. And the process is simple without requiring photolithography/etching processes having multiple masks. In addition, it can form process integration with the typical CMOS transistor, thereby shortening the required time for device fabrication. Furthermore, because the charge trapping layer is disposed at both sidewalls of the gate structure, two-bit data can be stored in a single memory cell, thus helping to increase device integration.

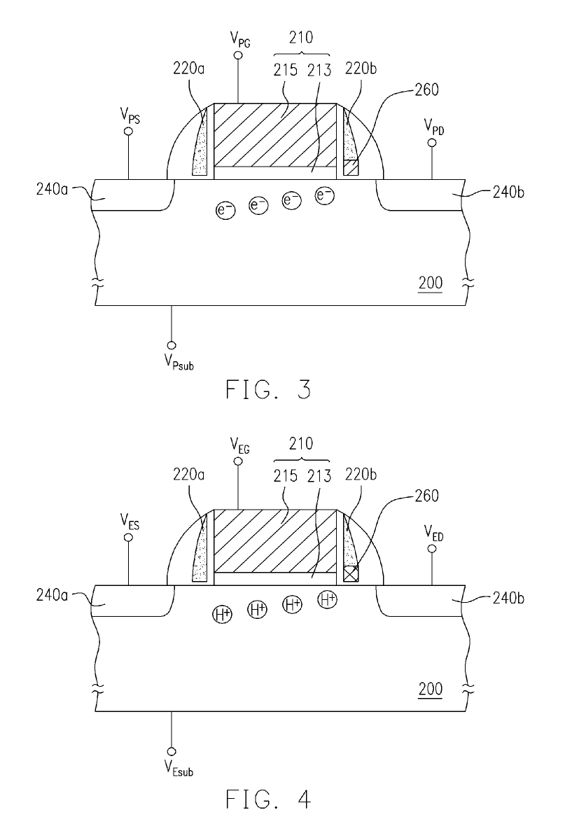

The following serve to describe the operating method for the aforementioned P-channel memory. Referring to FIG. 3 and FIG. 4, it includes a program operation schematic diagram (FIG. 3) and an erase operation schematic diagram (FIG. 4) for the P-channel memory.

Referring to FIG. 3 and FIG. 4, the present invention proposes an operating method for a P-channel memory. The P-channel memory includes, for example, the following: the substrate 200, the gate structure 210 disposed above the substrate 200, the charge trapping layer 220a and the charge trapping layer 220b disposed at both sidewalls of the gate structure 210, and the source/drain 240a and the source/drain 240b disposed in the substrate 200 at both sidewalls of the gate structure 210. Wherein, the gate structure 210 is, for example, constructed of the gate 215 and the gate dielectric layer 213.

The operating method for the P-channel memory is, for example, as described below. Referring to FIG. 3, during program operation, bias V_{PD} is applied at the source/drain 240b. It is, for example, about −3V to −4V. Bias V_{PS} is applied at the source/drain 240a. It is, for example, 0V. Bias V_{PG} is applied at the gate 215. It is about, for example, −0.5V to −1.5V. Bias V_{Psub} is applied to the substrate 200. It is about, for example, 0V to 1V. As a result, electrons can be injected into the charge trapping layer 220b to program the P-channel memory to store the bit 260. Wherein, the bias V_{PD} is less than the bias V_{PG}. The method for injecting electrons into the charge trapping layer 220b is, for example, channel hot electron injection method, Fowler-Nordheim Tunneling, or other suitable write methods.

Referring to FIG. 4, while conducting the erase operation, a bias V_{ED} is applied at the source/drain 240b. It is about, for example, −3V to −4V. A bias V_{ES} is applied at the source/drain 240a. It is, for example, 0 V. A bias V_{EG} is applied to the gate 215. It is about, for example, −2.5V to −3.5V. A bias V_{Esub} is applied to the substrate 200. It is about, for example, 2.8V to 3.4V. Wherein, the absolute value for the voltage difference between the bias V_{EG} and the bias V_{Esub} is less than or equal to 6V. The bias V_{ED} is less than the bias V_{EG}, and the bias V_{EG} is less than the bias V_{PG}. As the bias V_{Esub} is increased, the depletion region disposed below the gate structure 210 becomes more spacious. The strength of the electric field is increased also, thus can produce tertiary hot hole of higher energy. The tertiary hot hole mechanism is used to inject the hot hole into the charge trapping layer 220b, wherein the hole and the prior electron are mutually cancelled out. The bit 260 stored at the P-channel memory is therefore erased.

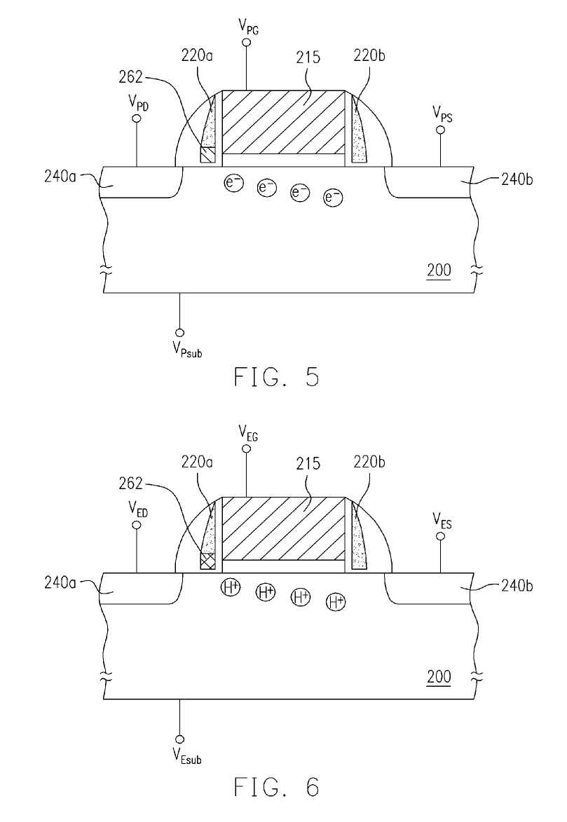

Furthermore, referring to FIG. 5 and FIG. 6, one can clearly understand the operating method for another bit. It includes the program operation schematic diagram illustrated in FIG. 5 and the erase operation schematic diagram illustrated in FIG. 6.

Referring to FIG. 5, during the program operation for the bit 262, the bias V_{PD} at the source/drain 240a is applied. It is for example, about −3V to −4V. A bias V_{PS} is applied at the source/drain 240b. It is, for example, 0V. A bias V_{PG} is applied at the gate 215. It is, for example, about −0.5V to −1.5V. A bias V_{Psub} is applied at the substrate 200. It is, for example, about 0V to 1V. Electrons are injected into the charge trapping layer 220a. And the bit 262 is stored into the P-channel memory. Wherein, the bias V_{PD} is less than the bias V_{PG}. The method for injecting the electrons into the charge trapping layer 220a can be channel hot electron injection method, Fowler-Nordheim Tunneling, or other suitable write methods.

Referring to FIG. 6, during the erase operation for the bit 262, a bias V_{ED} is applied at the source/drain 240a. It is, for example, about −3V to −4V. A bias V_{ES} is applied to the source/drain 240b. It is, for example, 0V. A bias V_{EG} is applied to the gate 215. It is, for example, about −2.5V to −3.5V. A bias V_{Esub} is applied to the substrate 200. It is, for example, is 2.8V to 3.4V. Wherein, the absolute value for the voltage difference of the bias V_{EG} and the bias V_{Esub} is less than or equal to 6V, the bias V_{ED} is less than the bias V_{EG}, and the bias V_{EG} is less than the bias V_{PG}. Using the tertiary hot hole mechanism to inject the hot hole into the charge trapping layer 220a, the already stored bit 262 of the P-channel memory is erased. In a single memory cell, two-bit data is wrote and erased.

The present invention proposes an operating method for a P-channel memory in which the operating speed for the device is shortened by the adoption of erase operations for tertiary hot hole mechanism. Benefits such as lowered required operating voltage, reduced power consumption, and increased program/erase efficiency are achieved. Because of the lowered operating voltage, current leakage issues can further be prevented, and thus device reliability is increased.

Furthermore, as a result of the charge trapping layer disposed at the sidewall of the gate structure, the charge storage is therefore found at both sides of the gate structure. And unlike the two bit for the conventional silicon nitride read only memory cell which will be mutually affected and produces the so-called electron secondary effect issues, it can also increase device reliability.

Based on the aforementioned, the present invention proposes a P-channel memory. Because the charge trapping layer is disposed at the sidewall of the gate structure, the device size can be greatly reduced by the structure. And the process is simple, and does not require photolithography process with multiple masks. And it can be integrated with typical Complementary MOS (CMOS) transistor process for shortening device fabrication time. Furthermore, as a result of the charge trapping layer disposed at the two sidewalls of the gate structure, two-bit data can therefore be stored in a single memory cell, thereby increasing device integration.

In addition, the present invention proposes an operating method for the P-channel memory in which the device operating speed is shortened by the adoption of the erase operations for the tertiary hot hole mechanism. Benefits therefore such as lowered required operating voltage, reduced power consumption, and increased program/erase efficiency are achieved. Because of the lowered operating voltage, current leakage issues can further be prevented, and device reliability is increased.

The P-channel memory for the present invention is different from the conventional silicon nitride read only memory. As a result of the charge trapping layer disposed at both sides of the gate structure, the same two bit for the memory cell therefore are not mutually affected to develop the so-called electron second injection effect issues, thereby increases device reliability.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A P-channel memory, having a first memory unit, wherein the first memory unit comprising:
a substrate;
a gate structure, disposed above the substrate;
a first charge trapping layer and a second charge trapping layer, disposed at both sidewalls of the gate structure for storing two bit at the first memory unit; and
a first source/drain and a second source/drain, disposed at both sidewalls of the gate structure in the substrate.

2. The P-channel memory according to claim 1, wherein the material for the first charge trapping layer and the second charge trapping layer is silicon nitride.

3. The P-channel memory according to claim 1, further comprising a tunnel dielectric layer between the first charge trapping layer and the sidewall of the gate structure and between the second charge trapping layer and the sidewall of the gate structure.

4. The P-channel memory according to claim 3, wherein the material for the tunnel dielectric layer comprises silicon oxide.

5. The P-channel memory according to claim 1, further comprising an insulation layer at the exterior side of the first charge trapping layer and the second charge trapping layer.

6. The P-channel memory according to claim 5, wherein the material for the insulation layer comprises silicon oxide.

7. The P-channel memory according to claim 1, wherein a P-type ion is doped in the first source/drain and the second source/drain.

8. The P-channel memory according to claim 1, further comprising a second memory unit, the second memory unit and the first memory unit having the same structure, and the first memory unit and the second memory unit sharing the first source/drain.

9. The P-channel memory according to claim 1, wherein the gate structure comprises a gate dielectric layer and a gate stacked on the substrate sequentially.

10. The P-channel memory according to claim 9, wherein the material for the gate comprises P-type polysilicon.

11. An operating method of a P-channel memory, the P-channel memory comprising a substrate, a gate disposed above the substrate, a first charge trapping layer and a second charge trapping layer disposed at both sidewalls of the gate, a first source/drain and a second source/drain disposed at both sidewalls of the gate in the substrate; and the operating method comprising:
injecting electrons into the second charge trapping layer while conducting program operation to store a first bit into the P-channel memory; and
applying a first voltage at the first source/drain, applying a second voltage at the second source/drain, applying a third voltage at the gate, and applying a fourth voltage at the substrate while conducting erase operation to use tertiary hot hole mechanism for injecting the hot hole into the second charge trapping layer to erase the first bit already stored inside the P-channel memory, wherein the absolute value of the voltage difference between the third voltage and the fourth voltage is less than or equal to 6 V and the second voltage is less than the third voltage.

12. The operating method of the P-channel memory according to claim 11, wherein the second charge trapping layer and the first bit are disposed on the same side.

13. The operating method of the P-channel memory according to claim 11, wherein conducting program operation further comprises:
applying a fifth voltage at the first source/drain;
applying a sixth voltage at the second source/drain;
applying a seventh voltage at the gate;
applying an eighth voltage at the substrate; and
injecting electrons into the second charge trapping layer to store the first bit into the P-channel memory, wherein the sixth voltage is smaller than the seventh voltage and the seventh voltage is larger than the third voltage .

14. The operating method of the P-channel memory according to claim 13, further comprising:
injecting electrons into the first charge trapping layer while conducting program operation to store a second bit into the P-channel memory;
applying the second voltage at the first source/drain;
applying the first voltage at the second source/drain;
applying the third voltage at the gate;
applying the fourth voltage at the substrate during the erase operation; and
using tertiary hot hole mechanism to inject hot hole into the first charge trapping layer to erase the second bit already stored inside the P-channel memory.

15. The operating method of the P-channel memory according to claim 14, wherein the first charge trapping layer and the second bit are disposed on the same side.

16. The operating method of the P-channel memory according to claim 14, during program operation, further comprising:
applying the sixth voltage at the first source/drain;
applying the fifth voltage at the second source/drain;
applying the seventh voltage at the gate;
applying the eighth voltage at the substrate; and
injecting electrons into the first charge trapping layer to store the second bit into the P-channel memory.

17. The operating method of the P-channel memory according to claim 11, wherein the first voltage is 0V, the second voltage is about −3V to −4V, the third voltage is about −2.5V to −3.5V, and the fourth voltage is about 2.8V to 3.4V.

18. The operating method of the P-channel memory according to claim 11, wherein method for inject electrons into the charge trapping layer comprises a channel hot electron injection (CHEI) method.

19. The P-channel memory according to claim 11, wherein the material for the first charge trapping layer and the second charge trapping layer is silicon nitride.

20. The P-channel memory according to claim 11, further comprising an insulation layer at the exterior side of the first charge trapping layer and the second charge trapping layer.
